(19) United States
(12) Patent Application Publication
(10) Pub. No.: US 2006/0172071 A1
(43) Pub. Date: Aug. 3, 2006

(54) Method of applying paint

(75) Inventors: Guylaine Marceau, Beauceville (CA); Sylvie Groleau, Saint-Isidore (CA)

Correspondence Address: BOURQUE & ASSOCIATES, P.A., 835 HANOVER STREET, SUITE 301, MANCHESTER, NH, 03104, US

(73) Assignee: Gecko Design Inc., Saint-Anselme (CA)

(21) Appl. No.: 11/231,523

(22) Filed: Sep. 21, 2005

Related U.S. Application Data
(63) Continuation of application No. 11/060,064, filed on Feb. 17, 2005, now abandoned.

(30) Foreign Application Priority Data
Feb. 17, 2004 (CA) 2,457,283

(51) Int. Cl. C23C 16/52; B05D 1/32

(52) U.S. Cl. 427/282; 427/8

(57) ABSTRACT

The present invention relates to a painting process allowing the application of paint on various types of surfaces, such as external surfaces of a bus for example, in order to allow the generation of a drawing, a design or a preconceived image on this same surface. More particularly the painting process includes the use of a series of means such as prepared drawings, adapted cut out vinyl-masks, masks, auxiliary accessories (stencils, rollers and sponges), instructions and specifications. The painting process allows the application of textures, minimizes the technical aid from the designers of the original drawing, is applicable to a great number of models of drawing and allows the repetition or the repair of a drawing of painting in factories or in workshops by industrial painters.

### FIELD OF THE INVENTION

The present invention relates to a painting process providing for the application of paint on various types of surfaces. More particularly, the painting process includes means of painting allowing for the generation of a drawing, a design or a preconceived image.

### BACKGROUND OF THE INVENTION

Even though artisanal/handcrafted drawings of paintings are prized, they pose problems when industrially produced because they are handmade by painters, often requiring a very long or undetermined time to reproduce. The delay involved in the reproduction of artisanal drawings of paintings is not well suited within the context of a production line. Moreover, these drawings of paintings are also unique and therefore difficult and expensive to accurately reproduce on several surfaces.

### SUMMARY OF THE INVENTION

The painting process is used to produce, within an industrial context, complex drawings of paintings which are similar to handmade paintings.

The painting process comprises prepared drawings, cut out vinyl-masks, masks, adapted auxiliary accessories (stencil, rollers and sponges), instructions and specifications in order to meet the needs of industrial painters as well as the requirements and the constraints of production in an industrial environment.

The painting process allows the reproduction of an original drawing and the application of textures and minimizes the technical aid from the designers of the original drawing. The painting process can also be applicable to a great number of models of drawings and allows the repetition or the repair of a drawing of a painting in the factory or workshop by industrial painters.

The painting process can be applied in the painting industry to heavy vehicles: caravans, motorized houses, buses, trucks and trailers as well as in the painting industry of planes and boats. Moreover, the painting process is usable in the painting industry of collection and competition cars, in the painting industry of various equipments such as household electrical appliances, machinery, vending machines and also in a general way in the industry of industrial painting and in workshops for the application of painting on medium and large surfaces.

The painting process usually consists of preparing a drawing from a model and which can comprise more than 2 colors. The prepared drawings are intended for the production of complex drawings of paintings in an industrial environment and in workshops using cut out vinyl-masks and cut out masks. The drawings are prepared in a specific way in order to fulfill the requirements of industrial production.

The painting process can also provide cut out vinyl-masks to painters in the industry of industrial painting and in workshops for the production of complex drawings of paintings, and cut out masks for the production of a painting in cut off vinyl-masks. The cut out vinyl-masks can comprise cut out or printed indications for the application of the colors.

The painting process can also provide cut out masks to painters in an industrial environment as well as in workshops, for the production of a painted drawing cut out in vinyl-masks.

The painting process allows for the use of multiple auxiliary accessories such as stencils and texture-rollers from the painting industry and adapted to the production of complex drawings of paintings generally carried out using cut out vinyl-masks and cut out masks.

The painting process can also provide painters in the painting industry with instructions and specifications for the production of a complex drawing of a painting starting from cut out vinyl-masks, masks and auxiliary accessories.

The painting process also provides for the preparation of a computer application allowing for the automated application of all the criteria specific to the production of a drawing intended for the cutting on a vinyl-mask and on the mask, as well as to the production of an industrial workshop painting.

### BRIEF DESCRIPTION OF THE DRAWINGS

FIG. 1 is a view showing a digitized artistic model of a painting which can be used in the painting process of the present invention.

FIG. 2 is a view showing a vectorized model of a painting corresponding to the digitized model of FIG. 1.

FIG. 3 is a view showing a retraced drawing corresponding to a portion of the vectorized model of FIG. 2.

FIG. 4 is a view showing a drawing with various painting colors.

FIG. 5 is a view showing a color-chart being used in the painting process of the present invention.

FIG. 6 is a view showing specifications corresponding to samples of paintings being used in the painting process of the present invention.

FIG. 7 is a view showing samples of colors of painting being used in the painting process of the present invention.

FIG. 8 is a view showing a portion of the drawing of FIG. 3 processed with a technique called “pinstripe” which can be used in the painting process of the present invention.

FIG. 9 is a view showing a drawing processed with a technique known as “color by color” which can be used in the painting process of the present invention.

FIG. 10 is a color view of the drawing of FIG. 3 which can be provided to painters in the painting process of the present invention together with the code specifications of the painting colors.

FIG. 11 is a view showing a color specification card comprising a diagram illustrating the drawing being used for the elaboration of the vinyl-mask as well as a specification grid being provided in the painting process of the present invention.

FIG. 12 is a view showing a piece of vinyl which can be cut out and used in the painting process of the present invention.

FIG. 13 is a view showing vinyl parts and instructions to be used in the painting process of the present invention.

FIG. 14 is a view showing a first step allowing for the positioning of a vinyl-mask being used in the painting process of the present invention.

FIG. 15 is a view showing a further step following the step as shown in FIG. 14, for the positioning of the vinyl-mask being used in the painting process of the present invention.

FIG. 16 is a view showing a further step following the step as shown in FIG. 15, for the positioning of the vinyl-mask being used in the painting process of the present invention.

FIG. 17 is a view showing a method of masking a vinyl-mask (vinyl-mask not shown) using a mask and masking ribbons, which can be used in the painting process of the present invention.

FIG. 18 is another view showing the method of masking as shown in FIG. 17, showing the vinyl-mask.

FIG. 19 is another view showing the method of masking a vinyl-mask using a mask and masking ribbons, which can be used in the painting process of the present invention.

FIG. 20 is a detailed view showing the method of masking as shown in FIG. 19.

FIG. 21 is another view showing the method of masking a vinyl-mask using a mask and masking ribbons which can be used in the painting process of the present invention.

FIG. 22 is a view showing an example of a mask to be installed on a vinyl-mask allowing for the application of painting colors, which can be used in the painting process of the present invention.

FIG. 23 is a view showing another example of a mask to be installed on a vinyl-mask allowing for the application of painting colors, which can be used in the painting process of the present invention.

FIG. 24 is a view showing another example of a mask to be installed on a vinyl-mask allowing the application of painting colors, which can be used in the painting process of the present invention.

FIG. 25 is a view showing another example of a mask to be installed on a vinyl-mask allowing the application of painting colors, which can be used in the painting process of the present invention.

FIG. 26 is a view showing another example of a mask to be installed on a vinyl-mask allowing the application of painting colors, which can be used in the painting process of the present invention.

FIG. 27 is a view showing another example of a mask to be installed on a vinyl-mask allowing the application of painting colors, which can be used in the painting process of the present invention.

FIG. 28 is a view showing an example of texture as obtained by the application of a roller painter, which can be used in the painting process of the present invention.

FIG. 29 is a view showing another example of texture as obtained by the application of a roller painter, which can be used in the painting process of the present invention.

FIG. 30 is a view showing another example of texture as obtained by the application of a roller painter, which can be used in the painting process of the present invention.

FIG. 31 is a view showing another example of texture as obtained by the application of a roller painter, which can be used in the painting process of the present invention.

FIG. 32 is a view showing another example of texture as obtained by the application of a roller painter, which can be used in the painting process of the present invention.

FIG. 33 is a view showing another example of texture as obtained by the application of a roller painter, which can be used in the painting process of the present invention.

### DETAILED DESCRIPTION OF ILLUSTRATIVE EMBODIMENTS

The present invention generally relates to a painting process, providing for the application of paint on various types of surfaces by means allowing for the sequential application of paint in order to generate a drawing, a design or a preconceived image. The painting process generally comprises a first step providing for the preparation of a drawing which can be effected from a model and intended to be produced for painting in an industrial environment or workshop. The model, digitized or not, can be a photograph, an artistic painting, a drawing, a sketch, an illustration or other, either in color or in black and white.

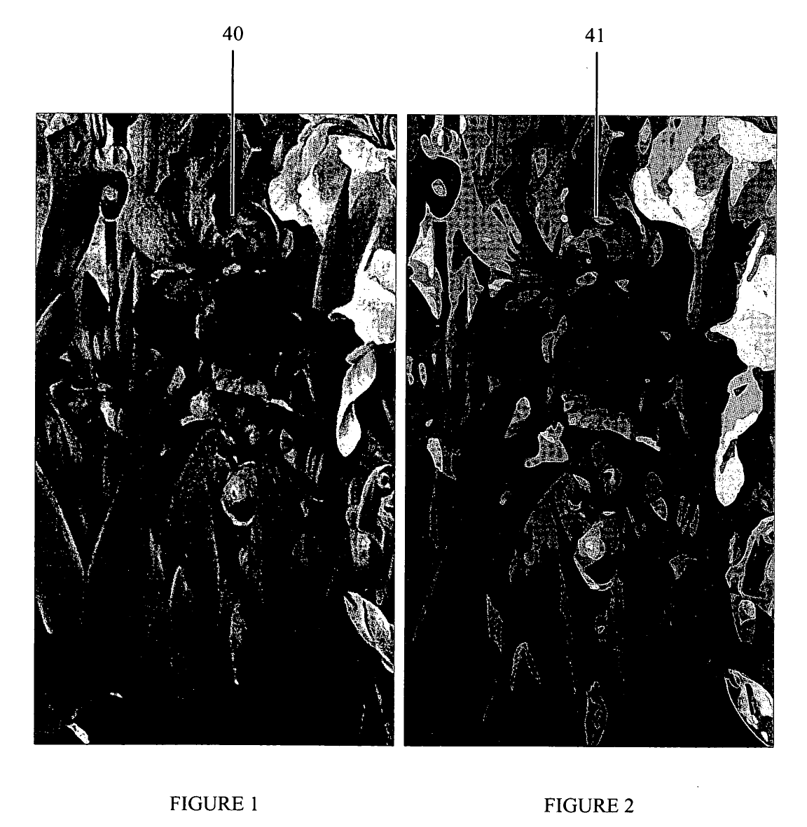

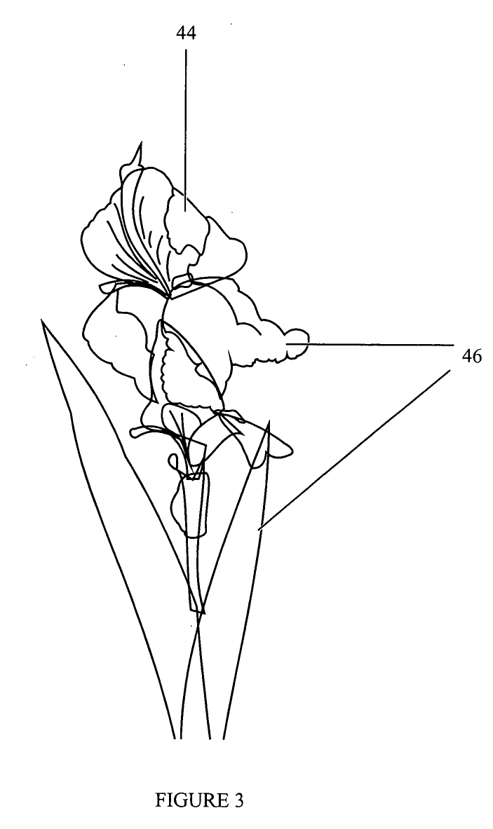

The techniques of digitalization, vectorization and redrawing of drawings are not new and thus will not be discussed in great detail hereinbelow. The painting process can include the use of digitalized drawing treatment techniques for the preparation of drawings used in industrial painting industries and in workshops. As shown in FIG. 1, the model 40 to be processed is digitized, if necessary. The digitized model 42 is vectorized as shown in FIG. 2. Finally, the outlines 44 of the drawing shown in FIG. 3 can be redrawn in order to reduce the quantity of nodal points resulting from the vectorization of model 42 in order to obtain an optimal and desired quantity and form size for the application of paint.

The drawing can then be worked over by a scaling of the surface to be painted while possibly also benefiting of a line treatment 46 of the drawing for a possible use in a subsequent step of the painting process as described hereinbelow.

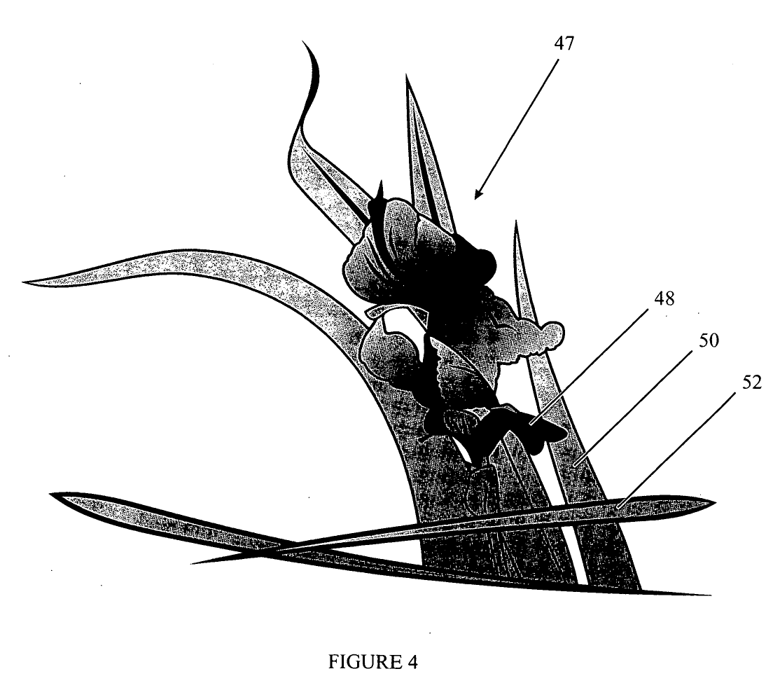

Also, the drawing can be processed such as to preserve the number of colors necessary for the application of paint, which is in excess of 2 colors. The standard for the color quantity in the industry of painting vehicles, is, for example, 2 to 7 colors, whereas drawing 47 as shown in FIG. 4 generally comprises from 2 to 24 colors (only 3 colors 48, 50 and 52 are shown in FIG. 4). For black and white models, the colors are added in order to obtain the desired number of tone nuances.

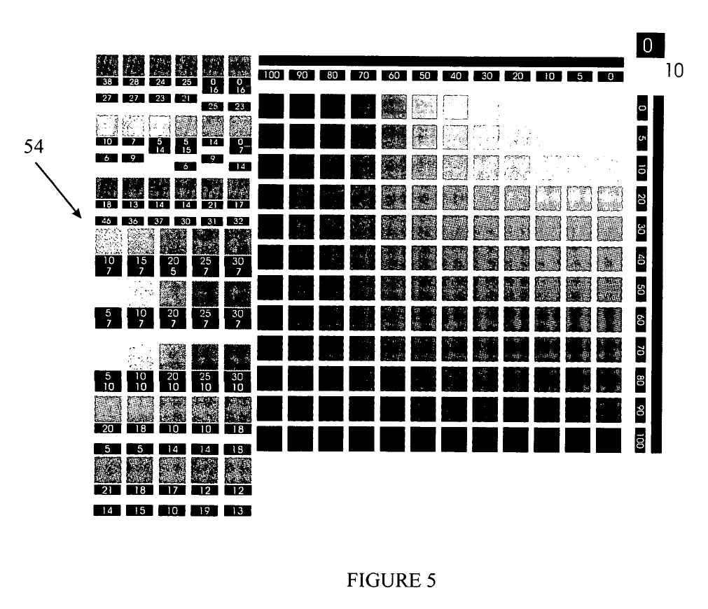

As illustrated in FIG. 5, the colors are selected in a chart 54 for laser, ink-jet or other kinds of printers. The chart is adjusted to correspond to samples of industrial painting colors, so that the colors of the printed drawing on paper are representative of the drawing to which paint is applied.

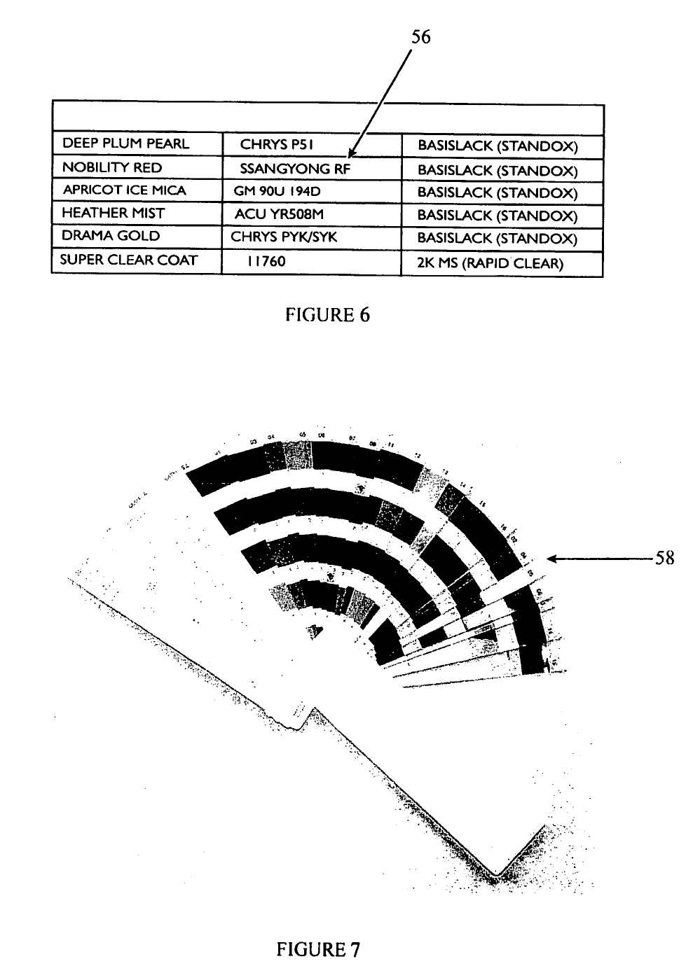

Concerning prepared drawings in the industry for painting vehicles, for example, the color charts 56 and 58 for the printer shown in FIGS. 6 and 7 are adjusted with the colors of the brands of paint used. If necessary, gradation colors are added with respect to the standards of the painting industry regarding mixtures of colors and lengths of application.

Once finished, the drawing 47 is transferred, in a second step, into a computer application which manages the pattern cutting from drawing 47 on a cutting machine. The drawing can be prepared by the computer application using different techniques such as “pinstripe” (by net or line of contour, “pinstripe” is the term usually used in the industry of painting vehicles) or “color by color”, or by a combination of the two techniques or any other technique allowing for the application of more than two colors.

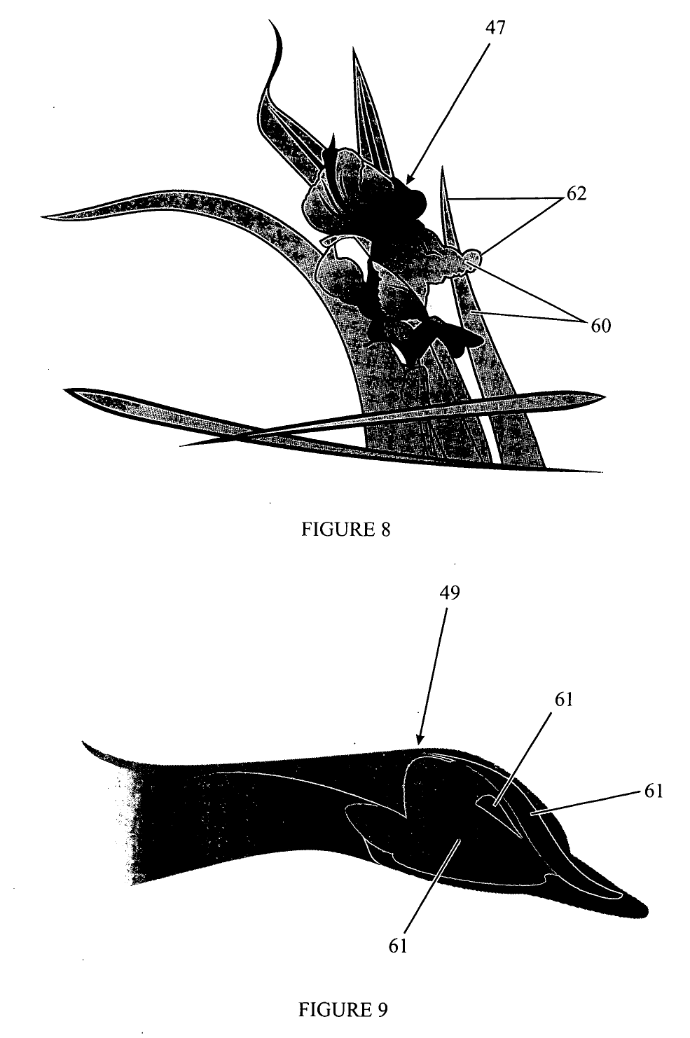

The “pinstripe” technique as illustrated in FIG. 8 consists in separating the closed forms 60 from each part of the drawing 47 by a space 62, so that they are not in contact. The spaces 62 represent a contour line (“pinstripe”) of the shapes on the drawing as made with paint and having its own color.

The technique known as “color by color” illustrated in FIG. 9 consists in placing the shapes 61 of drawing 49 side by side, without separation.

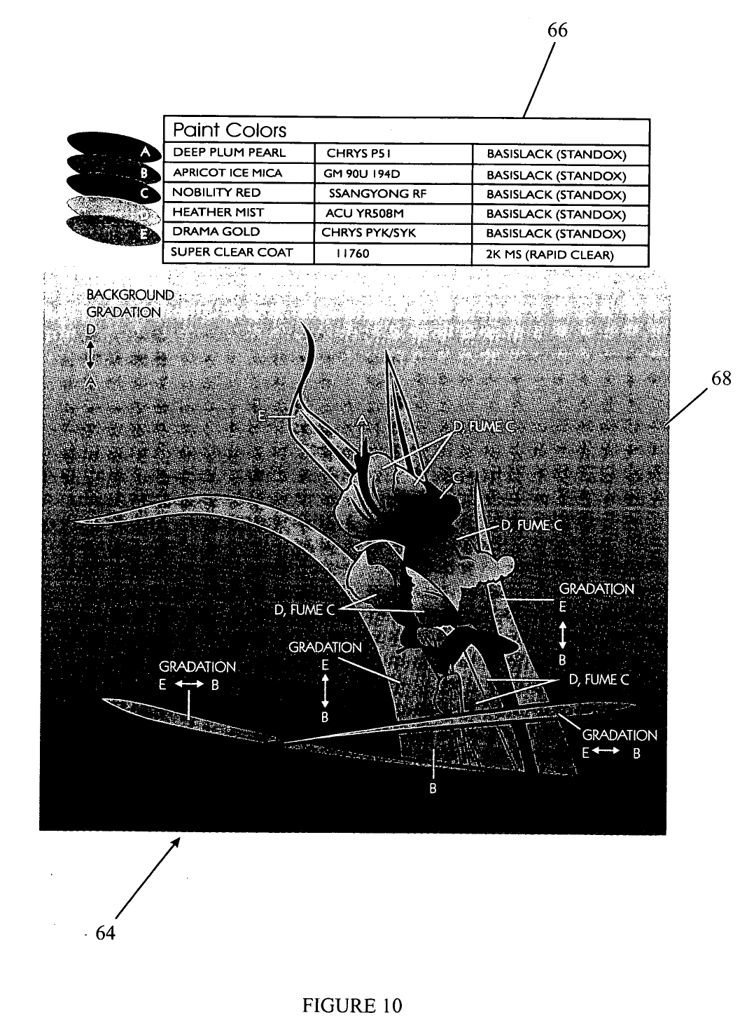

The painting process generally provides a card 64 (FIG. 10) of color specifications to painters for the application of a drawing of painting. The card 64 functions as a guide for the production of the complex drawing of painting, with the specifications 66 of the codes of painting colors. The card 64 also comprises a diagram 68 illustrating the shapes of the drawing which will be used in the painting process.

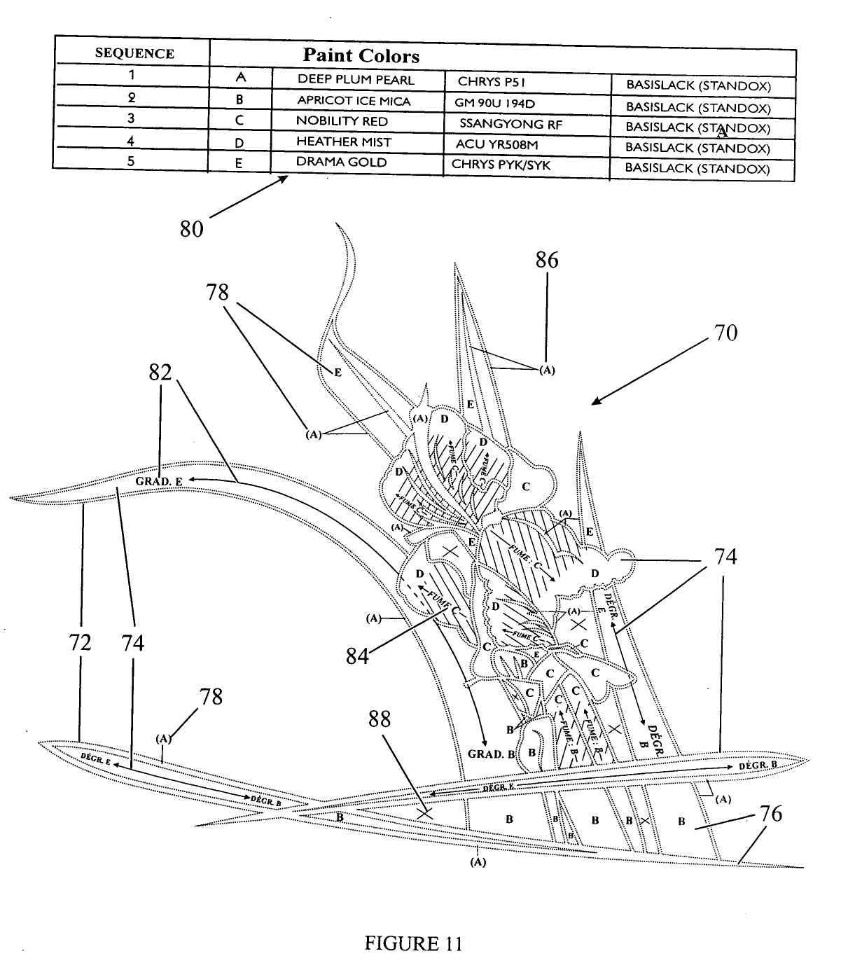

FIG. 11 shows the drawing 70 as prepared by computer application, and which incorporates the “pinstripe” technique. Indeed, the spaces 72 separate the closed shapes 74 from each other.

Each space 72 and closed shape 74 can correspond to a mask or a vinyl-mask in the painting process. Depending on the complexity of the drawing 70 and the level of detail to be reproduced, the masks and the vinyl-masks can be used together or separately to cover surfaces with paint or already painted areas. The mode of use and the technique of cutting vinyl-masks and masks will be explained hereinbelow.

The drawing 70 of FIG. 11 shows each shape in the production process of vinyl-masks 76, which is generally identified by a digit or a letter 78 and corresponding to the painting color to be applied. The digits or letters 78 generally refer to a grid 80 of specifications where the names, the codes and the brand of the painting colors to be used are registered.

With the “pinstripe” technique, the spaces 72 generally constitute the mask of the first color applied to the surface, prior to positioning the vinyl-mask 76 (see details below). In this case, one single piece of vinyl-mask 76 is used during the application of several colors of paint. Once positioned, the vinyl-mask 76 is never removed allowing the sticking and the removal process of masking ribbons and masks before the application of new layers of paint.

Regarding the technique known as “color by color”, it requires the preparation of a set of pieces of cut out vinyl-masks 76. During the application of paint for the production of the drawing, the painted shapes to be masked are covered from edge to edge by new vinyl pieces installed over the main piece of vinyl-mask.

The position and the direction of the application of gradation colors 82 and of “taints” 84 to be applied are generally indicated on the vinyl-masks 76. The mixture of the gradation colors 82 and the color of “taints” 84 are also generally indicated (schematically on FIG. 11) by digits or letters which refer to the grid 80 of specifications.

In the schematically illustrated configuration of FIG. 11, the digit or the letter in brackets 86 generally indicates the color applied to the surface to be painted prior the positioning of one or several cut out vinyl-masks 76. The outlined “X” 88 indicates the areas which need to be colored or the basic/background gradation to be applied following the production of the drawing 70.

The technique for creating “taints” 84 is not new. It consists of a coat of paint applied to a painting rifle in areas too small to receive the application of a gradation. The “taint” 84 creates a gradation effect. The paint is applied in a very dense way at the beginning of the “taint” 84 such that it entirely covers the underlying coat of paint. Then, it is applied in an increasingly less dense manner as the painting rifle is gradually moving in the areas to be painted. At the end of the “tainting” 84, the applied coat of paint is very thin, through which the color of the underlying paint layer can be clearly observed. The painting rifle comprises an apparatus used in the industry of painting, which pulverizes paint under the pressure of compressed air.

Various types of vinyl-masks 76 used in the painting process and the cutting process are illustrated in FIG. 12. The vinyls 76 generally comprise thin and flexible vinyl panels 90 temporarily coated with glue on at least one surface 92. A support paper 94 is glued to surface 92 which allows for the ready removal of the available vinyl panels 90, among others, in format of 12 inch, 24 inch, 36 inch and 48 inch rollers or more.

The vinyl pieces 76 can be glued directly on a vehicle, on a sign or another surface, or are printed and cut out then installed on a surface. The vinyl pieces 76 are generally cut out by knives on a cutting machine.

The cut out vinyl panels 90 can be covered with a transfer paper 96, which is coated with adhesive on a surface 98, thus holding the cut out pieces in the vinyl 90 to be installed on the surface to be painted in place, following removal of the support paper 94. The vinyl rollers can comprise punched tapes 100 allowing the activation of the vinyl rollers in the cutting machine during the cutting. The punched tapes 100 generally comprise dotted lines 102 for the withdrawal of the tapes 100. After the withdrawal of the punched tapes 100, the unnecessary pieces of the cut out vinyl 90 are removed and the transfer paper 96 is glued to the cut out vinyl panel 90.

Also, the painting process can generally provide painters with vinyl-masks 76 generated from drawing 70 (FIG. 11), cut out such that the vinyls masks 76 are similar or proportional to the drawing 70 and comprising instructions for the application of colors of a drawing of painting.

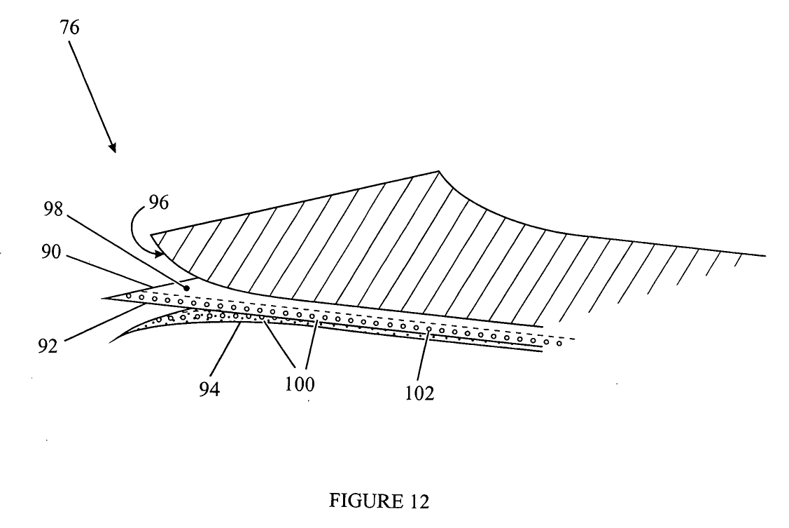

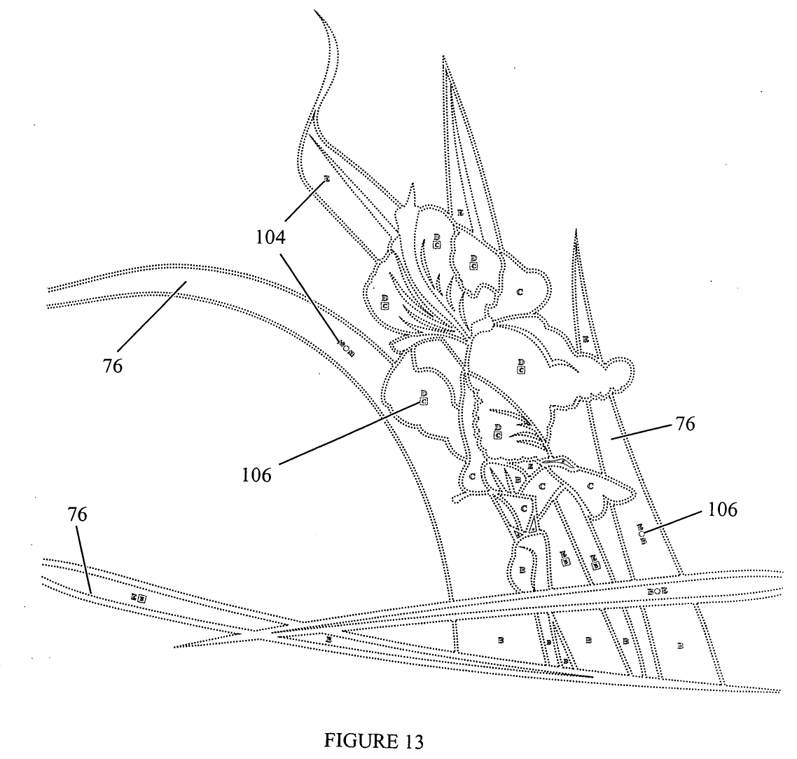

FIG. 13 shows an example of vinyl-mask pieces 76, cut out according to a drawing and provided to painters in an industrial environment and in a workshop. The pieces 76 can first of all be installed on a surface covered with a first layer of color paint, according to the instructions of card 64, given to painters. The indications of the shapes of the drawing cut out from the vinyl-mask 76 consist of digits or letters referring to the code of the color of painting to be applied in each shape, as explained earlier for the diagram of the drawing to be painted according to the color specifications card (80 on FIG. 11).

The process of creating vinyl-masks 76 comprises certain steps, the result being illustrated in FIG. 13. The digits or letters 104 can be directly cut out in the vinyl 76 on the cutting machine during the cutting of the vinyl shapes 76. In some cases, (drawings with very small shapes, for instance) the digits or the letters can be printed before, after or during the cutting process, rather than being cut out in the vinyl. Pictograms (square, circle, triangle or other) accompanying the digits or the letters indicate the application of a gradation range 106 or of a “taint” 108.

The indications cut out in the cut out vinyl-mask 76 are removed before the application of paint so that a vacuum is formed in the vinyl-mask, thus allowing the previously applied color layer to be seen and the indications to be easily identified by eye. The printed indications can be covered with a piece of masking ribbons or another material, if the paint must be applied directly on the vinyl-mask 76. After the paint application, the piece of masking ribbon is removed in order to make the indication visible again.

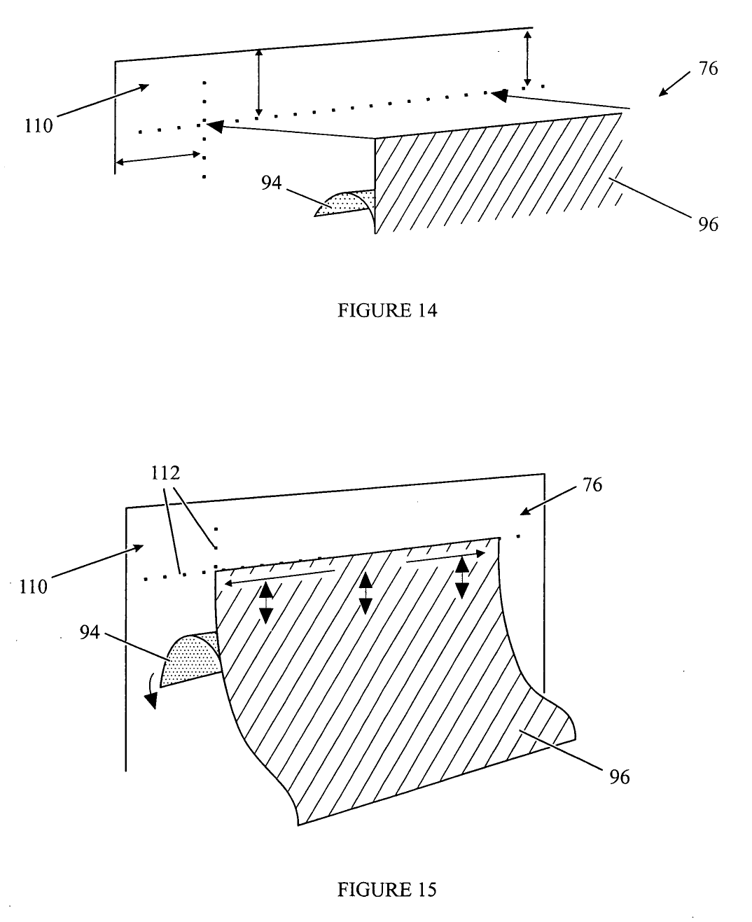

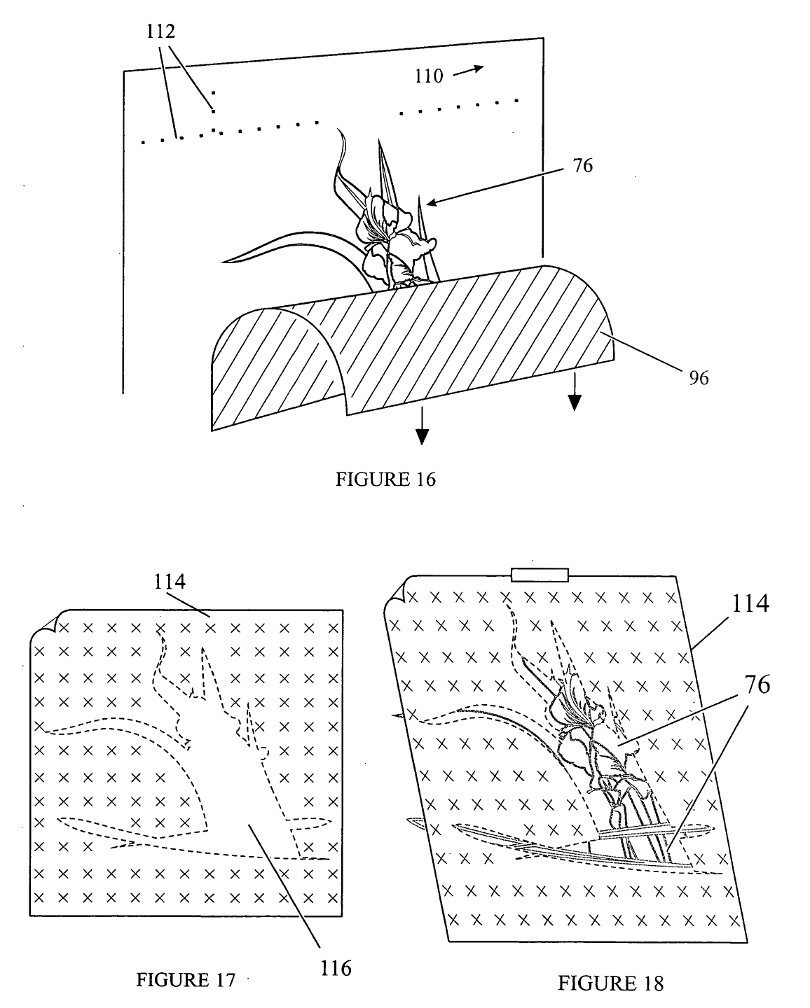

The method of positioning a vinyl-mask is illustrated in FIGS. 14 to 16. The cut out vinyls 76 are glued and separated from a generally smooth surface 110, to be painted or already painted. These vinyls 76, and the glue used to coat them, are tested and do not cause damage to the surface and applied paint.

The cut out vinyls 76 are used during the production of complex drawings of painting made using several colors in order to hide portions of already painted surface. In doing so, those portions do not receive paint and paint can be applied to the parts which do not have vinyls. The vinyls available in the industry are designed to be installed according to a tested method.

To install a vinyl on a surface, a small part of the support paper 94 of the vinyl is detached over the whole width of the top of the piece. The detached part of the vinyl covered with transfer paper is glued on the surface 110 to be painted or already covered with a first layer of painting color. The surface 110 is generally cleaned beforehand to allow a good adhesion of the part of the vinyl which is coated with adhesive (part of vinyl installed on the support paper 94).

The detached part of the vinyl covered with transfer paper 96 is generally positioned on a guiding mark 112 at right angles, and which can be drawn beforehand with a chalk, a pencil or a masking ribbon on the surface to be painted 110. The guiding mark 112 allows the vinyl-mask to be positioned at the desired location on the surface to be painted. When the detached part of the vinyl (where the support paper 94 is removed) is glued over the width of the surface 110, the support paper 94 is gradually removed from the vinyl by pulling downwards. As the support paper 94 is removed, the still covered vinyl glued to the transfer paper 96, is glued to the surface 110 to be painted, exerting a pressure applicable by hand or using a smooth and non-cutting instrument in order to smoothen the vinyl covered with transfer paper 96, towards the outside of the piece. In doing so, pleating of the vinyl or creation of air bubbles under the surface of the vinyl-mask 76 is prevented. When the support paper 94 is entirely removed and the surface of the vinyl-mask 76 is fixed, the transfer paper 96 is removed by pulling slowly downwards, so as to avoid the detachment of the vinyl shapes 76 installed on the surface to be painted 110.

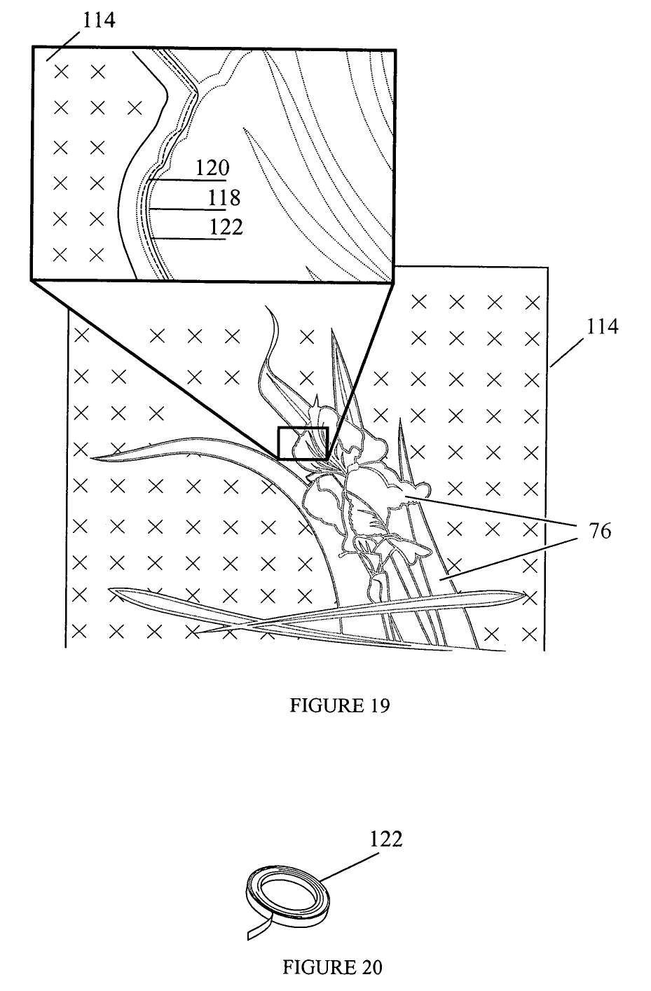

As shown in FIGS. 17 to 20, the painting process can also provide painters with one or more masks 114 which are generally non-sticking and which can be made out of paper, plastic or generally any other not-sticking material comprising cut out sections 116 corresponding to the drawing cut out in the vinyl-mask 76. The cut out masks 114 are installed on the vinyl-mask 76 in order to protect the areas of the surface which should not receive a coat of paint.

The cut out sections 116 of the first cut out mask 114 are identical to the external contour 118 of the vinyl-mask 76 with interior “overlap” 120 (overlapping zone), which covers the external part of the contour 118 of the vinyl-mask on a surface varying from ⅛ in. to ⅜ in. towards the interior.

For example, the cut out mask 114 can cover the first coat of paint on the surface to be painted without using the vinyl-mask 76, which allows the removal of the shapes cut out from the vinyl-mask 76 through the cut out section 116 without removing the cut out mask 114.

The cut out masks 114 prepared for the application of other painting colors with the shapes of the installed vinyl-masks 76 can avoid the masking of the joints between the others vinyl-masks 76 where painting is not wanted. The masking ribbon 122 ensures the water tightness of the joints to paint.

To remove the masks 114 or the masks made with masking ribbons 122, the painters cut out the masking ribbons 122 using a knife, while avoiding marking the painting under the mask 114. The use of cut out masks 114 imposes a limit to the number of maskings using masking ribbons 122, as well as to the number of necessary knife cuts, thus protecting the quality of the applied painting. Moreover the use of masks 114 also allows to save time in the production by reducing the quantity of masking ribbons 122 to apply. It only requires the removal of the handmade cuttings and it minimizes the time for the installation of several regular masks. The cut out masks 114 can also prevent the occurrences of detachment or tearing of the shapes of the vinyl-mask 76 during the withdrawal of large quantities of masking ribbons 122.

The painting process according to the present invention can also provide painters with an instruction card for the use of the masks 114 designed for the painting of a drawing cut out in a vinyl-mask 76. The mask 114 is generally made of a resistant paper, which is available in rollers of 36 inches, 48 inches or another size used by painters in order to protect areas of a painted surface during the application of painting.

For its installation, the cut out mask 114 comprising the cut out section 116, can be adjusted on the vinyl-mask 76, followed by gluing to the top of the surface, covered with the first coat of paint with masking ribbons 122, in order to temporarily hold it in place. The edges of the mask 114 can also be glued temporarily, if necessary.

The “overlap” 120 of the mask is glued on the vinyl-mask 76 with masking ribbons 122 of generally ½ inch. Once glued, the masking ribbon 122 is generally smoothed by exerting a pressure to prevent the leakage of paint. At least one layer of masking ribbons 122 is generally added by shifting towards the outside of the cut out section 116 of the mask 114, in order to ensure a better water tightness of the joint between the mask 114 and the vinyl-mask 76.

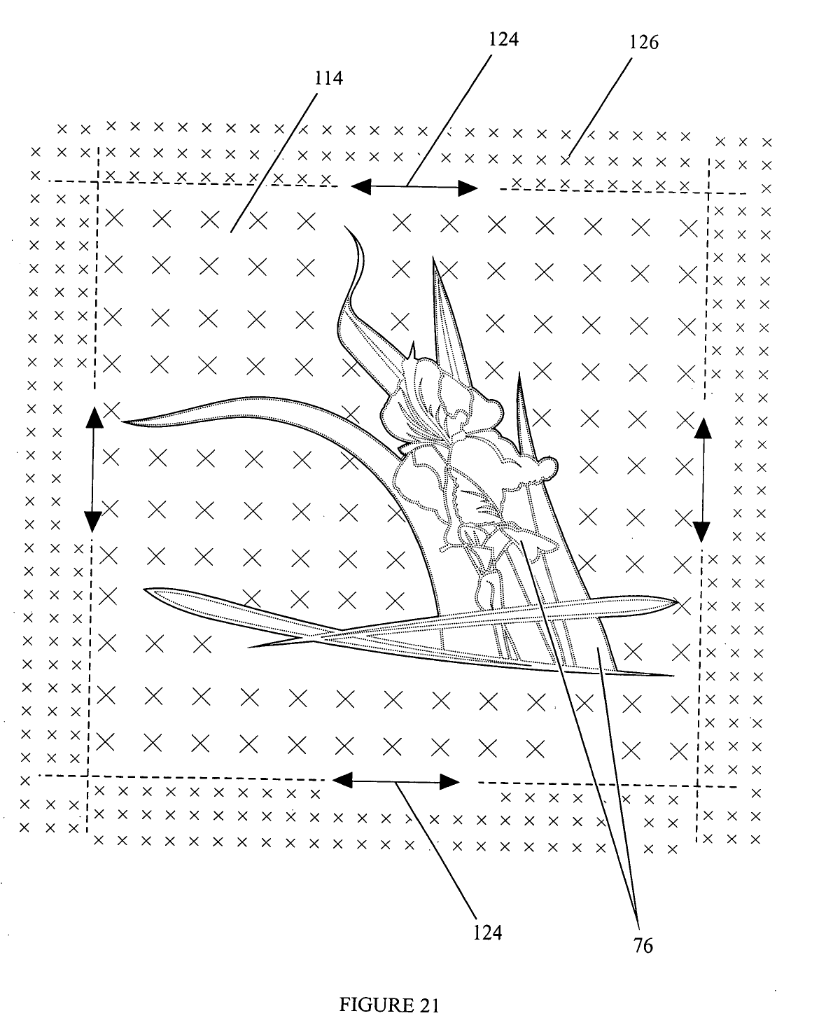

Once glued on the vinyl-mask 76, the external sides 124 of the cut out mask 114 are glued on the surface generally covered with the first coat of paint with masking ribbons 122, as shown in FIG. 21. Another masking paper 126 can then be adjusted and glued around the cut out mask 114 such as to entirely mask the surface covered with the first coat of paint or a surface to be protected from painting.

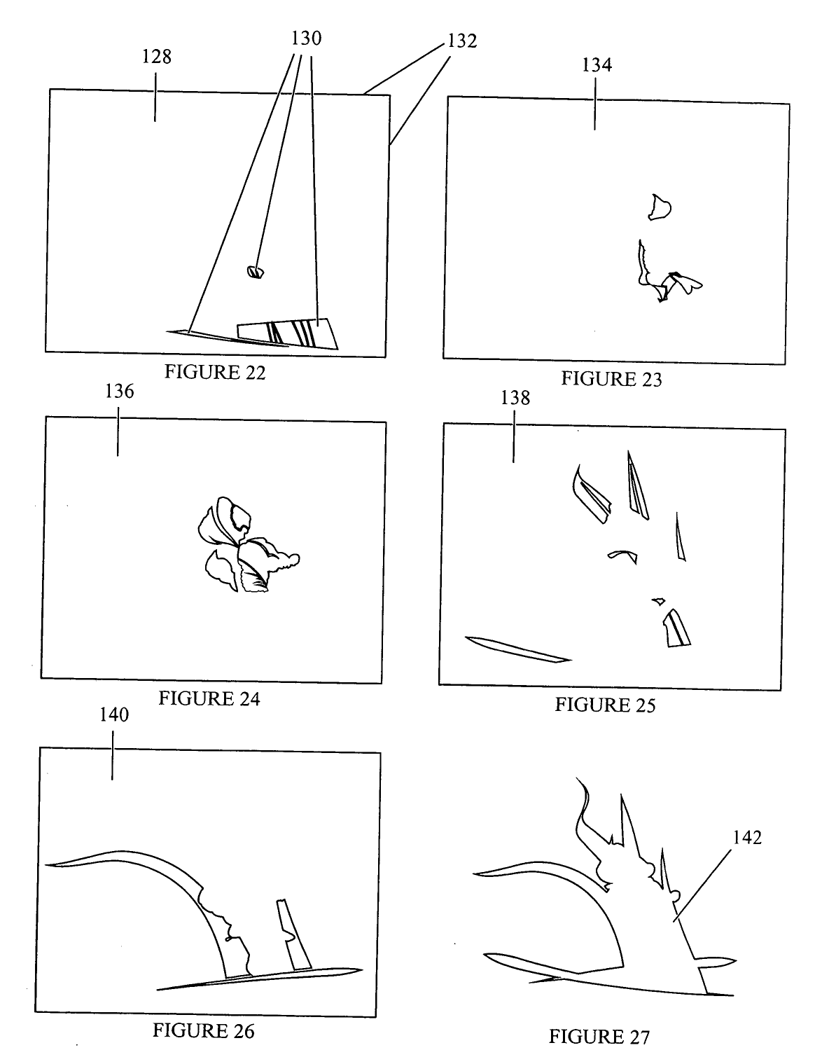

As shown in the FIG. 22, another mask 128 can be installed. The cut out zones 130 of this mask 128 are glued on the vinyl-mask 76 and its contours 132 are glued on the mask installed on the surface (126 in FIG. 21) according to the method described hereinabove. Generally, no other mask is to be installed at this step. The shapes (generally corresponding to zones 130) corresponding to the color which the painter wishes to apply are removed from the vinyl-mask 76 such as to discover the generally equivalent areas on the surface to be painted.

When the painted surface is dry (the time for drying the painting is determined by the painters according to standards of painting manufacturers), the cut out mask 128 is removed, according to the regular methods used in industry. The steps of installation of all other cut out masks (134, 136, 138, and 140 shown on the FIGS. 23 to 26) are repeated for the application of the other colors as well as for the application of the range gradations and of taints.

The painting process can also provide painters with a cut out mask 142 covering only the installed vinyl-mask 76, as shown in FIG. 27. The cut out mask 142 protects the painted drawing during the application of a color or a color gradation on the background (around the drawing). The cut out mask 142 for drawing is slightly smaller than the vinyl-mask 76 allowing its installation close to the contour of the vinyl-mask by using masking ribbons while avoiding gluing the ribbon on the surface to be painted.

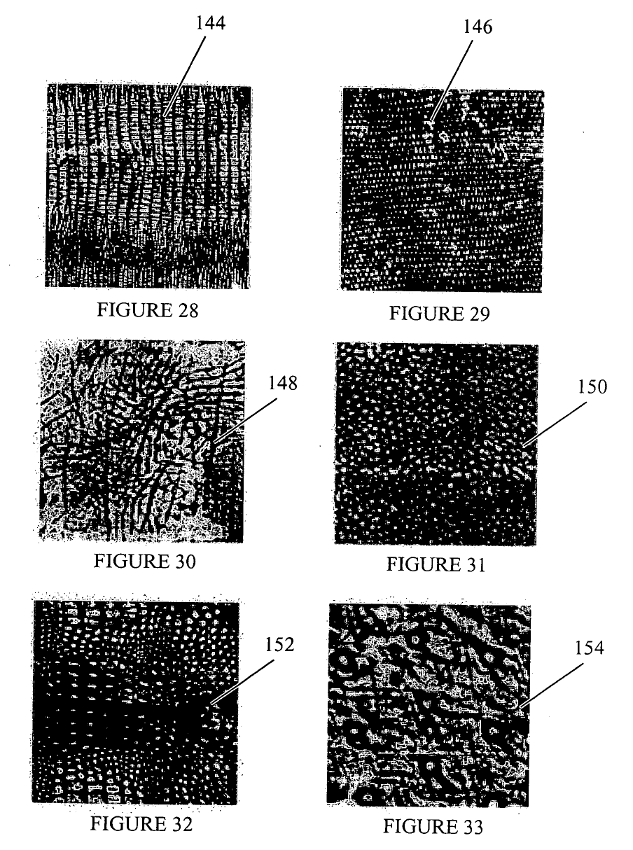

The painting process also provides painters with auxiliary accessories, for industries and adapted to the production of complex drawings of paintings made with vinyl-masks and cut out masks. The accessories can include stencils made of pieces of aluminum, PVC, rigid paperboard and rigid vinyl or any other solid material which can be cut out on a cutting machine. The stencils are generally used to hide portions of painted surfaces in order to apply a coat of paint of another color for repetitive drawings distributed in an unequal or random way. During the application of paint, the stencils held by hand are moved slightly to obtain a blur effect around the drawing. The accessories also comprise rollers and painting sponges for the production of textures 144, 146, 148, 150, 152, 154 as shown in FIGS. 28 to 29. Those sponges are generally prepared to accompany the complex drawings of paintings made using vinyl-masks and cut out masks or for their own production.

The painting process can also include a computer application allowing for the automated application of all the criteria specific to the production of a drawing designed for the cutting of vinyl-masks and masks, and for the production of a painting in an industrial workshop, as described in the preceding paragraphs. The application gathers together all the parameters for the production of a complex drawing of painting made with vinyl-masks, masks and using auxiliary accessories (stencils, sponges and rollers).

The application evaluates the number of dimensions in which the vinyl-mask and painting must be applied and uses the technique of the trompe l'oeil to display, in 3 dimensions, the drawing to be painted on the equipment. The application takes into account the real scales of the equipment to be painted. The application allows the digitalization of an image and the defining of zones to be redrawn, which separate the colors while allowing shading effects. The application converts colors of RGB, CMYK or Pantone towards the chart of industrial paintings, evaluates the order of application of the colors and the conflicts in the proximity of 2 colors (pigmentation) in addition to the different kinds of compatible coatings (for example: metal vs. solid). The application allows for the drafting of the painting estimate (cards of instructions and specifications) as well as the printing of the cards and the estimates.

Although the invention was described in connection with a particular configuration illustrated in the included figures, modifications and additions can be made without changing the spirit thereof.

1. A method for painting a surface comprising the following steps:
analyzing an image in order to identify a plurality of basic components of said image;
using said plurality of basic components to create a model;
using said model to create overall means, a plurality of masking means and means of painting guide;
attaching said overall means to said surface; and
using said plurality of masking means with said means of painting guide to paint said surface.

2. A method for painting a surface as described in the claim 1, wherein the means of painting guide includes means of indications on how to use said means of masking to paint said surface.

3. A method to paint a surface as described in the claim 1, wherein the step of using the means of masking comprises the following steps:
setting one by one the means of masking on the overall means; and
painting the surface.
